(19) United States
(12) Patent Application Publication
(10) Pub. No.: US 2023/0007974 A1
(43) Pub. Date: Jan. 12, 2023

(54) SEMICONDUCTOR STRUCTURE AND MANUFACTURING METHOD THEREOF

(71) Applicant: CHANGXIN MEMORY TECHNOLOGIES, INC., HEFEI CITY (CN)

(72) Inventor: Tzung-Han LEE, Hefei City (CN)

(21) Appl. No.: 17/808,812

(22) Filed: Jun. 24, 2022

(30) Foreign Application Priority Data
Jul. 9, 2021 (CN) 202110779531.5

(51) Int. Cl. H01L 21/8234; H01L 27/088; H01L 29/49

(52) U.S. Cl. CPC H01L 21/82345; H01L 27/088; H01L 29/49

(57) ABSTRACT

The present disclosure relates to a semiconductor structure and a manufacturing method thereof. The method includes providing a substrate, where the substrate includes a device region and a peripheral region; and forming a bit line structure in the device region, and forming a transistor structure in the peripheral region, where the transistor structure includes a gate structure, and the bit line structure includes a bit line conductive layer and a bit line protective layer; the gate structure includes a gate oxide layer, a high-k dielectric layer, a gate conductive layer and a gate protective layer; the gate conductive layer and the bit line conductive layer are obtained by patterning a same conductive material layer, and the bit line protective layer and the gate protective layer are obtained by patterning a same protective material layer.

### CROSS-REFERENCE TO RELATED APPLICATION

This application claims the priority of Chinese Patent Application No. 202110779531.5, submitted to the Chinese Intellectual Property Office on Jul. 9, 2021, the disclosure of which is incorporated herein in its entirety by reference.

### TECHNICAL FIELD

The present application relates to the technical field of semiconductors, in particular to a semiconductor structure and a manufacturing method thereof.

### BACKGROUND

In the present semiconductor process, the device structure located in the device region and the device structure located in the peripheral region are generally formed through independent processes. Taking the bit line structure in the device region and the transistors in the peripheral region as an example, generally, bit line structures are formed first in the device region, and then transistors are formed in the peripheral region. The two forming processes are independent of each other, which results in complicated process steps, high production costs, and low production efficiency.

### SUMMARY

According to an aspect, the present disclosure provides a manufacturing method of a semiconductor structure. The manufacturing method includes:

providing a substrate, where the substrate includes a device region and a peripheral region located at a periphery of the device region;

forming a gate oxide material layer in the peripheral region of the substrate, and forming a high-k dielectric material layer on an upper surface of the gate oxide material layer; and

forming a bit line structure in the device region, and forming a transistor structure in the peripheral region, where the transistor structure includes a gate structure; the bit line structure includes a bit line conductive layer and a bit line protective layer located on an upper surface of the bit line conductive layer; and the gate structure includes:

a gate oxide layer;

a high-k dielectric layer, located on an upper surface of the gate oxide layer;

a gate conductive layer, located on the high-k dielectric layer; and

a gate protective layer, located on an upper surface of the gate conductive layer; where

the gate conductive layer and the bit line conductive layer are obtained by patterning a same conductive material layer, the bit line protective layer and the gate protective layer are obtained by patterning a same protective material layer, the gate oxide layer is obtained by patterning the gate oxide material layer, and the high-k dielectric layer is obtained by patterning the high-k dielectric material layer.

The present disclosure further provides a semiconductor structure, including:

a substrate, where the substrate includes a device region and a peripheral region located at a periphery of the device region;

a bit line structure, located in the device region, where the bit line structure includes a bit line conductive layer and a bit line protective layer located on an upper surface of the bit line conductive layer; and

a transistor structure, located in the peripheral region, where the transistor structure includes a gate structure, and the gate structure includes:

a gate oxide layer;

a high-k dielectric layer, located on an upper surface of the gate oxide layer;

a gate conductive layer, located on the high-k dielectric layer; and

a gate protective layer, located on an upper surface of the gate conductive layer; where

the gate conductive layer and the bit line conductive layer are obtained by patterning a same conductive material layer, the bit line protective layer and the gate protective layer are obtained by patterning a same protective material layer.

### BRIEF DESCRIPTION OF THE DRAWINGS

To describe the technical solutions in the embodiments of the present application or in the conventional art more clearly, the following briefly describes the accompanying drawings required for describing the embodiments or the conventional art. Apparently, the accompanying drawings in the following description show merely some embodiments of the present application, and a person of ordinary skill in the art may still derive other drawings from these accompanying drawings without creative efforts.

FIG. 1 is a flowchart of a manufacturing method of a semiconductor structure according to an embodiment of the present application;

FIG. 2 is a schematic structural diagram of a structure obtained in step S1 in the manufacturing method of a semiconductor structure according to an embodiment of the present application;

FIG. 3 and FIG. 4 are schematic structural diagrams of a structure obtained in step S2 in the manufacturing method of a semiconductor structure according to an embodiment of the present application;

FIG. 5 is a flowchart of the manufacturing method of a semiconductor structure after step S2 according to an embodiment of the present application;

FIG. 6 is a flowchart of step S4 in the manufacturing method of a semiconductor structure according to an embodiment of the present application;

FIG. 7 and FIG. 8 are schematic structural diagrams of a structure obtained in step S4 in the manufacturing method of a semiconductor structure according to an embodiment of the present application;

FIG. 9 is a flowchart of step S3 in the manufacturing method of a semiconductor structure according to an embodiment of the present application;

FIG. 10 is a schematic structural diagram of a structure obtained in step S31 in the manufacturing method of a semiconductor structure according to an embodiment of the present application;

FIG. 11 is a schematic structural diagram of a structure obtained in step S31 in a device region in the manufacturing method of a semiconductor structure according to an embodiment of the present application;

FIG. 12 is a schematic structural diagram of a partial device region in a structure obtained before step S33 in the manufacturing method of a semiconductor structure according to an embodiment of the present application;

FIG. 13 is a schematic structural diagram of a partial peripheral region in a structure obtained in step S34 in the manufacturing method of a semiconductor structure according to an embodiment of the present application;

FIG. 14 is a schematic structural diagram of a structure after a protective material layer, a gate conductive material layer, a polysilicon material layer, a high-k dielectric material layer, and a gate oxide material layer are patterned in the manufacturing method of a semiconductor structure according to an embodiment of the present application; and FIG. 14 is further a schematic structural diagram of a semiconductor structure according to an embodiment of the present application;

FIG. 15 is a schematic structural diagram of a structure obtained after step S3 in the manufacturing method of a semiconductor structure according to an embodiment of the present application; and FIG. 15 is further a schematic structural diagram of a semiconductor structure according to another embodiment of the present application; and

FIG. 16 is a flowchart of step S3 in the manufacturing method of a semiconductor structure according to another embodiment of the present application.

### DETAILED DESCRIPTION

To facilitate the understanding of the present application, the present application is described more completely below with reference to the accompanying drawings. The preferred embodiments of the present application are shown in the accompanying drawings. However, the present application may be embodied in various forms without being limited to the embodiments described herein. On the contrary, these embodiments are provided to make the present application more thorough and comprehensive.

Unless otherwise defined, all technical and scientific terms used herein have the same meaning as commonly understood by those skilled in the technical field of the present application. The terms mentioned herein are merely for the purpose of describing specific embodiments, rather than to limit the present application.

It should be understood that when an element or layer is described as “being on”, “being adjacent to”, “being connected to” or “being coupled to” another element or layer, it can be on, adjacent to, connected to, or coupled to the another element or layer directly, or intervening elements or layers may be present. On the contrary, when an element is described as “being directly on”, “being directly adjacent to”, “being directly connected to” or “being directly coupled to” another element or layer, there are no intervening elements or layers. It should be understood that although terms such as first, second, and third may be used to describe various elements, components, regions, layers, doped types and/or sections, these elements, components, regions, layers, doped types and/or sections should not be limited by these terms. These terms are only used to distinguish one element, component, region, layer, doped type or section from another element, component, region, layer, doped type or section. Thus, a first element, component, region, layer, doped type or section discussed below could be termed a second element, component, region, layer, doped type or section without departing from the teachings of the present disclosure. For example, a first metal-work-function laminated layer may be referred to as a second metal-work-function laminated layer, and similarly, the second metal-work-function laminated layer may be referred to as the first metal-work-function laminated layer. The first metal-work-function laminated layer and the second metal-work-function laminated layer are of different doped types.

Spatial relationship terms such as “under”, “beneath”, “lower”, “below”, “above”, and “upper” can be used herein to describe the relationship shown in the figure between one element or feature and another element or feature. It should be understood that in addition to the orientations shown in the figure, the spatial relationship terms further include different orientations of used and operated devices. For example, if a device in the accompanying drawings is turned over and described as being “beneath another element”, “below it”, or “under it”, the device or feature is oriented “on” the another element or feature. Therefore, the exemplary terms “beneath” and “under” may include two orientations of above and below. In addition, the device may further include other orientations (for example, a rotation by 90 degrees or other orientations), and the spatial description used herein is interpreted accordingly.

In this specification, the singular forms of “a”, “an” and “the/this” may also include plural forms, unless clearly indicated otherwise. It should also be understood that terms “include” and/or “comprise”, when used in this specification, may determine the presence of features, integers, steps, operations, elements and/or components, but do not exclude the presence or addition of one or more other features, integers, steps, operations, elements, components and/or groups. In this case, in this specification, the term “and/or” includes any and all combinations of related listed items.

Embodiments of the present disclosure are described herein with reference to cross-sectional illustrations that are schematic diagrams of idealized embodiments (and intermediate structures) of the present disclosure, such that variations shown in the shapes can be contemplated due to, for example, manufacturing techniques and/or tolerances. Therefore, the embodiments of the present disclosure should not be limited to the specific shapes of the regions shown herein, but include shape deviations due to, for example, manufacturing technologies. Therefore, the regions shown in the figure are schematic in nature, and their shapes are not intended to show the actual shapes of the regions of the device and limit the scope of the present disclosure.

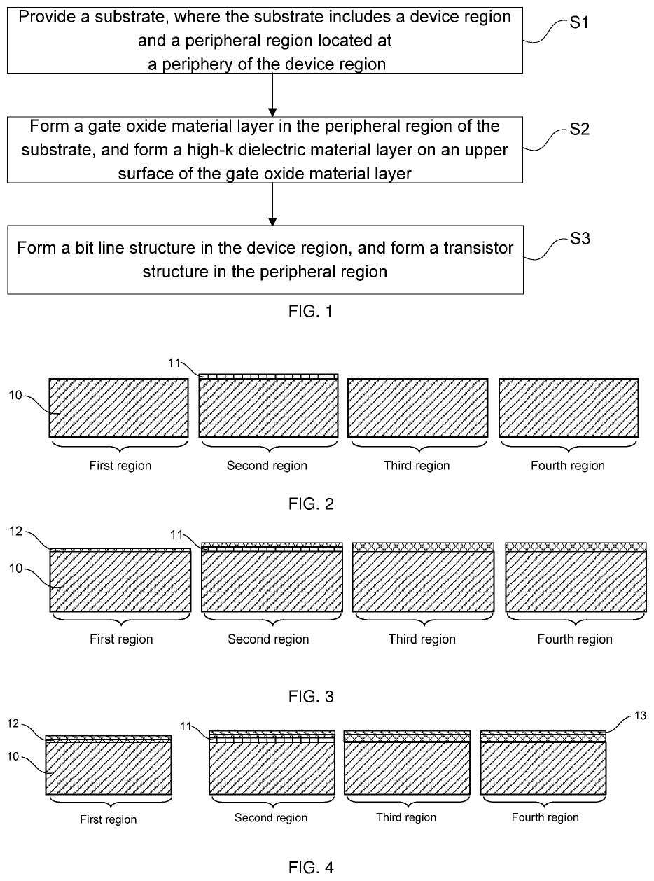

With reference to FIG. 1 to FIG. 15, a manufacturing method of a semiconductor structure provided in the present application includes:

S1: Provide a substrate 10, where the substrate 10 includes a device region and a peripheral region located in a periphery of the device region;

S2: Form a gate oxide material layer 12 in the peripheral region of the substrate 10, and form a high-k dielectric material layer 13 on an upper surface of the gate oxide material layer 12; and

S3: Form a bit line structure in the device region, and form a transistor structure in the peripheral region.

The transistor structure includes a gate structure. The bit line structure includes a bit line conductive layer and a bit line protective layer located on an upper surface of the bit line conductive layer. The gate structure includes a gate oxide layer 2, a high-k dielectric layer 3, a gate conductive layer 7, and a gate protective layer 8. The high-k dielectric layer 3 is located on an upper surface of the gate oxide layer 2. The gate conductive layer 7 is located on an upper surface of the high-k dielectric layer 3. The gate protective layer 8 is located on an upper surface of the gate conductive layer 7. The gate conductive layer 7 and the bit line conductive layer are obtained by patterning a same conductive material layer. The bit line protective layer and the gate protective layer 8 are obtained by patterning a same protective material layer 18. The gate oxide layer 2 is obtained by patterning the gate oxide material layer 12. The high-k dielectric layer 3 is obtained by patterning the high-k dielectric material layer 13.

According to the manufacturing method of a semiconductor structure provided by the present application, patterning the same conductive material layer obtains the gate conductive structure in the gate structure and the bit line conductive layer in the bit line structure at the same time, and patterning the same protective material layer obtains the bit line protective layer and the gate protective layer at the same time, such that the process of forming the bit line structure in the device region partially overlaps the process of forming the transistor structure in the peripheral region, and the bit line structure in the device region and the transistor in the peripheral region are formed at the same time in the same process, thereby simplifying the process steps, saving the production costs, and improving the production efficiency.

Specifically, in step S1, with reference to FIG. 2, the substrate 10 is provided, and the substrate 10 includes the device region and the peripheral region located in the periphery of the device region.

The peripheral region may include a first region, a second region, a third region, and a fourth region. The first region, the second region, the third region, and the fourth region are respectively used to form different device structures, and may be used to form, for example, transistors in different types.

In an embodiment, the substrate 10 may include but is not limited to a via substrate. The material of the substrate 10 is not specifically limited in the present application.

In an embodiment, a step of forming a buried gate word line 9 in the device region may be included between step S2 and step S3.

In step S2, with reference to step S2 in FIG. 1 and FIG. 3 and FIG. 4, the gate oxide material layer 12 is formed in the peripheral region of the substrate 10, and the high-k dielectric material layer 13 is formed on an upper surface of the gate oxide material layer 12.

The thickness of the gate oxide material layer 12 in the first region and the second region may be smaller than that of the gate oxide material layer 12 in the third region and the fourth region.

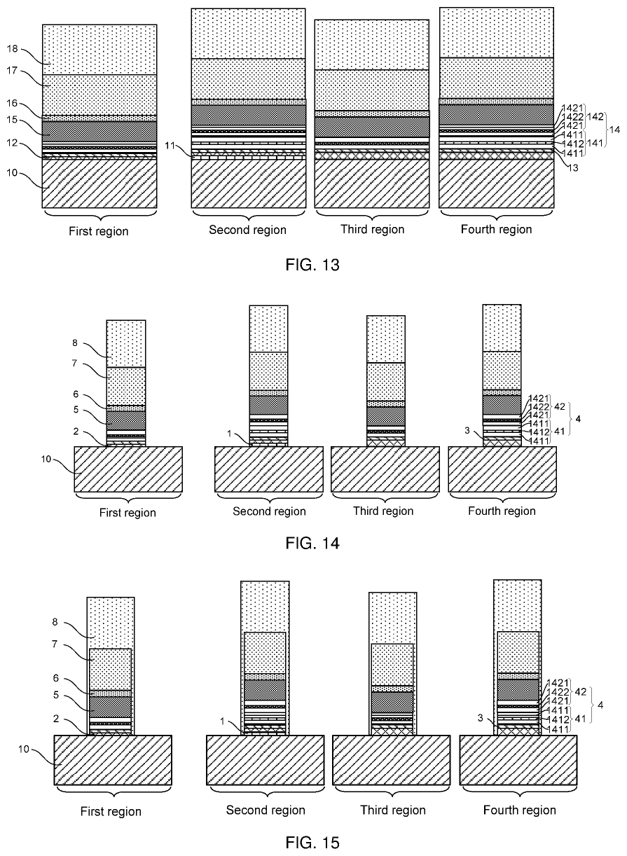

In step S3, the bit line structure is formed in the device region, and the transistor structure is formed in the peripheral region. With reference to FIG. 13 and FIG. 14, FIG. 13 is a schematic diagram of a partial cross-sectional structure of the peripheral region in the structure obtained after the protective material layer, the gate conductive material layer, the polysilicon material layer, the high-k dielectric material layer, and the gate oxide material layer are formed. FIG. 14 is obtained after the structure in FIG. 13 is patterned. The gate structure includes the gate oxide layer 2, the high-k dielectric layer 3, the gate conductive layer 7 and the gate protective layer 8. The high-k dielectric layer 3 is located on the upper surface of the gate oxide layer 2. The gate conductive layer 7 is located on the high-k dielectric layer 3. The gate protective layer 8 is located on the upper surface of the gate conductive layer 7. The gate conductive layer 7 and the bit line conductive layer are obtained by patterning the same conductive material layer, the bit line protective layer and the gate protective layer 8 are obtained by patterning the same protective material layer 18, the gate oxide layer 2 is obtained by patterning the gate oxide material layer 12, and the high-k dielectric layer 3 is obtained by patterning the high-k dielectric material layer 13.

The conductive material layer is a gate conductive material layer 17.

In an embodiment, after step S3, the method may further include: the gate protective layer 8 keeps growing to cover the gate oxide layer 2, the high-k dielectric layer 3 and the gate conductive layer 7.

According to the manufacturing method of a semiconductor structure provided in the foregoing embodiments, the gate protective layer covers the gate oxide layer, the high-k dielectric layer, and the gate conductive layer, thereby avoiding the impact of the subsequent process on the gate structure.

In an embodiment, as shown in FIG. 2 to FIG. 4, the peripheral region includes the first region, the second region, the third region, and the fourth region. As shown in FIG. 15, the transistor structure includes a first transistor structure located in the first region, a second transistor structure located in the second region, a third transistor structure located in the third region, and a fourth transistor structure located in the fourth region. The first transistor structure includes a first gate structure, the second transistor structure includes a second gate structure, the third transistor structure includes a third gate structure, and the fourth transistor structure includes a fourth gate structure.

In an embodiment, the first transistor structure is a thin oxygen N-type transistor, the second transistor structure is a thin oxygen P-type transistor, the third transistor structure is a thick oxygen N-type transistor, the fourth transistor structure is a thick oxygen P-type transistor. Further, the first transistor structure may be a thin oxygen NMOS transistor, the second transistor structure may be a thin oxygen PMOS transistor, the third transistor structure may be a thick oxygen NMOS transistor, the fourth transistor structure may be a thick oxygen PMOS transistor.

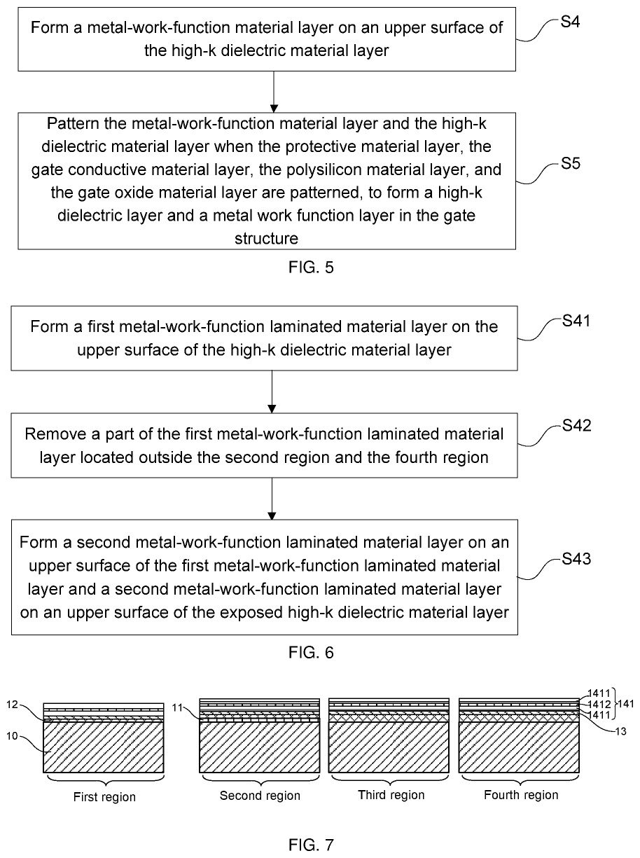

With reference to FIG. 5, in an embodiment, after step S2, the method may further include:

S4: Form a metal-work-function material layer 14 on an upper surface of the high-k dielectric material layer 13.

When the protective material layer 18, the gate conductive material layer 17, the polysilicon material layer 15, and the gate oxide material layer 12 are patterned, the metal-work-function material layer 14 and the high-k dielectric material layer 13 are patterned, to form a metal work function layer 4 in the gate structure.

In an embodiment, before step S2, the method may further include: form a trench material layer 11 in the second region.

In an embodiment, the trench material layer 11 is patterned when the protective material layer 18, the gate conductive material layer 17, the polysilicon material layer 15, and the gate oxide material layer 12 are patterned, to form a trench layer 1 in the second gate structure of the second transistor structure.

Specifically, the trench layer 1 may include, but is not limited to a germanium layer or a silicon germanium layer. The trench layer 1 is used to enhance the stress of the substrate, increase the mobility of holes, and improve the performance of the PMOS transistor formed subsequently.

Specifically, with reference to FIG. 6, in an embodiment, step S4 may further include:

S41: Form a first metal-work-function laminated material layer 141 on the upper surface of the high-k dielectric material layer 13, and as shown in FIG. 7, the first metal-work-function laminated material layer 141 may include first work function layers 1412 and first gate metal layers 1411 laminated alternately and sequentially from bottom to top;

S42: Remove a part of the first metal-work-function laminated material layer 141 located outside the second region and the fourth region; and

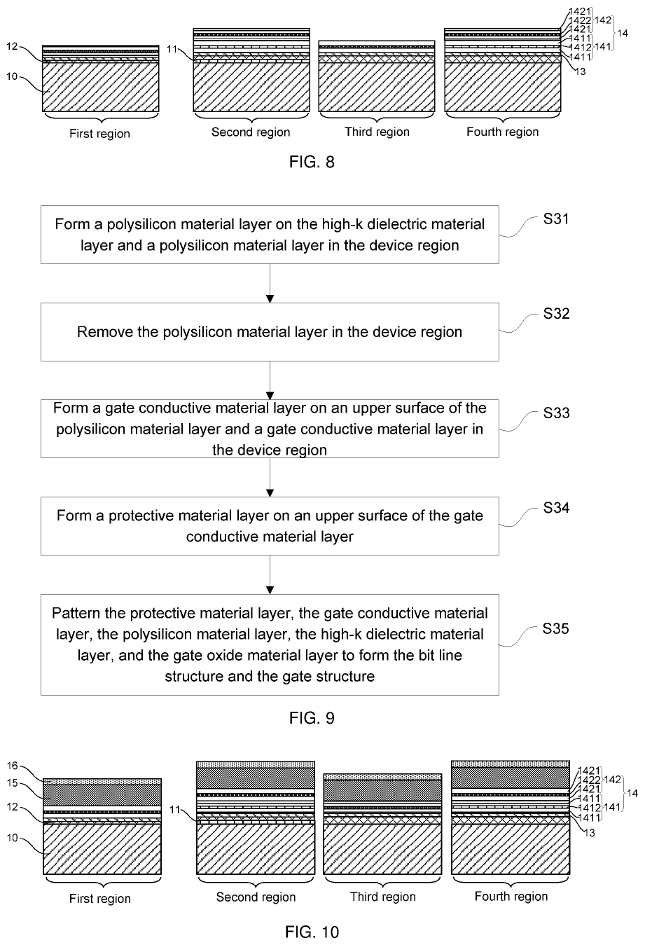

S43: Form a second metal-work-function laminated material layer 142 on an upper surface of each of the first metal-work-function laminated material layers 141 and a second metal-work-function laminated material layer 142 on an upper surface of the exposed high-k dielectric material layer 13, where as shown in FIG. 8, the second metal-work-function laminated material layer 142 may include second work function layers 1422 and second gate metal layers 1421 laminated alternately and sequentially from bottom to top, a first metal-work-function laminated layer 41 is the structure obtained by patterning the first metal-work-function laminated material layer 141, and a second metal-work-function laminated layer 42 is the structure obtained by patterning the second metal-work-function laminated material layer 142.

It may be noted that the high-k dielectric material layer 13 may be further formed in the device region. The first metal-work-function laminated material layer 141 in step S41 may be located in the device region. In step S42, the part of the first metal-work-function laminated material layer 141 located outside the second region and the fourth region in the peripheral region and the first metal-work-function laminated material layer 141 located in the device region are removed.

The first work function layer 1412 may include an aluminum element, the second work function layer 1422 may include a lanthanide element, and the material of the first gate metal layer 1411 and the material of the second gate metal layer 1421 may be titanium nitride (TiN) or thallium nitride (TaN).

Specifically, the metal-work-function material layer 14 in the second gate structure and the metal-work-function material layer 14 in the fourth gate structure each include a first metal-work-function material layer 141 and a second metal-work-function material layer 142, and the metal-work-function material layer 14 in the first gate structure and the metal-work-function material layer 14 in the third gate structure each include a second metal-work-function material layer 142. The high-k dielectric material layer 13 is further formed in the device region.

The metal work function layer 4 is a structure obtained by patterning the metal-work-function material layer 14.

With reference to FIG. 9, in an embodiment, the gate structure further includes a polysilicon layer 5. The polysilicon layer 5 is located on the high-k dielectric layer 3. The gate conductive layer 7 is located on an upper surface of the polysilicon layer 5. Based on the foregoing embodiments, step S3 may include:

S31: Form a polysilicon material layer 15 on the high-k dielectric material layer 13 and a polysilicon material layer 15 in the device region, where specifically, when the metal-work-function material layer 14 is formed, the following steps are performed;

S32: Remove the polysilicon material layer 15 in the device region;

S33: Form a gate conductive material layer 17 on an upper surface of the polysilicon material layer 15 and a gate conductive material layer 17 in the device region;

S34: Form a protective material layer 18 on an upper surface of each of the gate conductive material layers 17, as shown in FIG. 13; and

S35: Pattern the protective material layer 18, the gate conductive material layer 17, the polysilicon material layer 15, the high-k dielectric material layer 13, and the gate oxide material layer 12 to form the bit line structure and the gate structure.

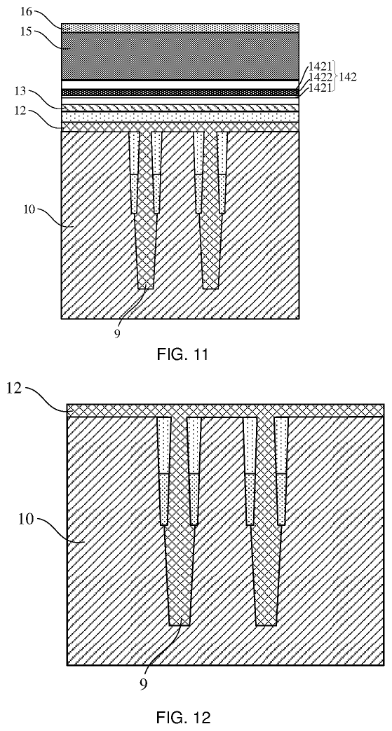

It should to be noted that when the metal-work-function material layer 14 is formed, step S31 is the step of forming the polysilicon material layer 15 on the metal-work-function material layer 14 and the polysilicon material layer 15 in the device region. With reference to FIG. 10, in an embodiment, the following step may be included between step S31 and step S32: Form a polysilicon protective material layer 16 on an upper surface of the polysilicon material layer 15. In this embodiment, FIG. 11 is a schematic diagram of a partial cross-sectional structure of the device region in the structure obtained after step S31.

Based on the foregoing embodiments, after step S32, and before step S33, the method may include the following step: Remove the second metal-work-function laminated material layer 142 in the device region and the high-k dielectric material layer 13 in the device region.

With reference to FIG. 12, FIG. 12 is a schematic diagram of a structure obtained in the device region in the step of removing the second metal-work-function laminated material layer 142 in the device region and the high-k dielectric material layer 13 in the device region.

In this embodiment, FIG. 14 is a schematic diagram of a partial cross-sectional structure of the peripheral region in the structure obtained after step S35.

For example, as shown in FIG. 15, after step S35, the method further includes a step in which a bit line sidewall is formed on a sidewall of the bit line structure, and a gate sidewall is formed on a sidewall of the gate structure. Materials of the bit line sidewall and the gate sidewall may be the same as that of the protective material layer 18.

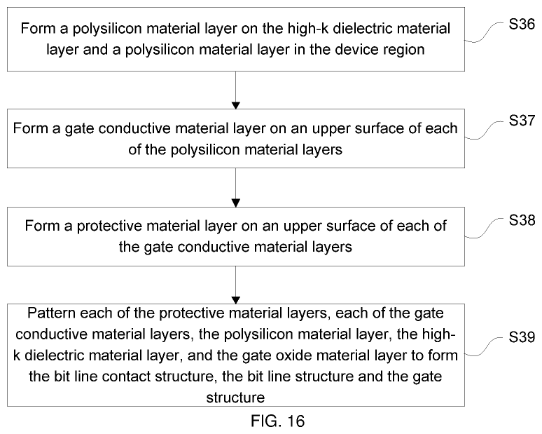

With reference to FIG. 16, the present application further provides another embodiment. Compared with the embodiments in FIG. 1 to FIG. 15, in this embodiment, in the processes of forming the bit line structure in the device region and forming the gate structure in the peripheral region, a bit line contact structure (not shown) is also formed in the device region, and the bit line contact structure is located between the bit line structure and the substrate 10 and is in contact with the bit line structure; the gate structure further includes the polysilicon layer 5, the polysilicon layer 5 is located on the high-k dielectric layer 3, the gate conductive layer 7 is located on an upper surface of the polysilicon layer 5, and the polysilicon layer 5 and the bit line contact structure are obtained by patterning the same polysilicon material layer 15.

The difference between the embodiment in FIG. 16 and the embodiments in FIG. 1 to FIG. 15 is step S3. In the embodiment of the FIG. 16, step S3 may include:

S36: Form a polysilicon material layer 15 on the high-k dielectric material layer 13 and a polysilicon material layer 15 in the device region;

S37: Form a gate conductive material layer 17 on an upper surface of each of the polysilicon material layers 15;

S38: Form a protective material layer 18 on an upper surface of each of the gate conductive material layers 17; and

S39: Pattern the protective material layer 18, the gate conductive material layer 17, the polysilicon material layer 15, the high-k dielectric material layer 13, and the gate oxide material layer 12 to form the bit line contact structure, the bit line structure and the gate structure.

According to the manufacturing method of a semiconductor structure provided in the foregoing embodiment, the same polysilicon material layer 15 is patterned to obtain the polysilicon layer 5 in the gate structure and the bit line contact structure in the bit line structure at the same time, thereby further simplifying the process steps, saving the production costs, and improving the production efficiency.

The manufacturing steps of the other structures in the embodiment of FIG. 16 are the same as those in the embodiments of FIG. 1 to FIG. 15, which is not described in detail herein.

With reference to FIG. 14 and FIG. 15, the present application further provides a semiconductor, including a substrate 10, a bit line structure, and a transistor structure. The substrate 10 includes a device region and a peripheral region at a periphery of the device region. The bit line structure is located in the device region, and includes a bit line conductive layer and a bit line protective layer located on an upper surface of the bit line conductive layer. The transistor structure is located in the peripheral region and includes a gate structure. The gate structure includes a gate oxide layer 2, a high-k dielectric layer 3, a gate conductive layer 7, and a gate protective layer 8. The high-k dielectric layer 3 is located on an upper surface of the gate oxide layer 2. The gate conductive layer 7 is located on the high-k dielectric layer 3. The gate protective layer 8 is located on an upper surface of the gate conductive layer 7. The gate conductive layer 7 and the bit line conductive layer are obtained by patterning a same conductive material layer. The bit line protective layer and the gate protective layer 8 are obtained by patterning a same protective material layer 18.

The semiconductor structure provided by the present application is formed by patterning the same conductive material layer obtains the gate conductive structure and the bit line conductive layer, and patterning the same protective material layer obtains the bit line protective layer and the gate protective layer, such that in the process of manufacturing the semiconductor structure, the process of forming the bit line structure in the device region partially overlaps the process of forming the transistor structure in the peripheral region, and the bit line structure in the device region and the transistor in the peripheral region can be formed at the same time in the same process, thereby simplifying the process steps, saving the production costs, and improving the production efficiency.

In an embodiment, the semiconductor structure may further include a bit line contact structure. The bit line contact structure is located in the device region and located between the bit line structure and the substrate 10.

In an embodiment, the gate structure further includes a polysilicon layer 5. The polysilicon layer 5 is located on the high-k dielectric layer 3. The gate conductive layer 7 is located on an upper surface of the polysilicon layer 5.

In an embodiment, the polysilicon layer 5 and the bit line contact structure are obtained by patterning a same polysilicon material layer 15.

The polysilicon layer 5 and the bit line contact structure are obtained by patterning the same polysilicon material layer 15, thereby simplifying the process steps, saving the production costs, and improving the production efficiency.

With reference to FIG. 14 and FIG. 15, in an embodiment, the gate structure further includes a metal work function layer 4 located on an upper surface of the high-k dielectric layer 3. The polysilicon layer 5 is located on an upper surface of the metal work function layer 4.

With reference to FIG. 14 and FIG. 15, in an embodiment, the peripheral region includes a first region, a second region, a third region, and a fourth region, the transistor structure includes a first transistor structure located in the first region, a second transistor structure located in the second region, a third transistor structure located in the third region, and a fourth transistor structure located in the fourth region; the first transistor structure includes a first gate structure, the second transistor structure includes a second gate structure, the third transistor structure includes a third gate structure, and the fourth transistor structure includes a fourth gate structure; the metal work function layer 4 in the second gate structure and the metal work function layer 4 in the fourth gate structure each include a first metal-work-function laminated layer 41 and a second metal-work-function laminated layer 42, and the metal work function layer 4 in the first gate structure and the metal work function layer 4 in the third gate structure each include a second metal-work-function laminated layer 42.

With reference to FIG. 14 and FIG. 15, in an embodiment, the first metal-work-function laminated layer 41 includes first gate metal layers 1411 and first work function layers 1412 laminated alternately and sequentially from bottom to top, and a top layer of the first metal-work-function laminated layer 41 is the first gate metal layer 1411; and the second metal-work-function laminated layer 42 includes second work function layers 1422 and second gate metal layers 1421 laminated alternately and sequentially from bottom to top, and a top layer of the second metal-work-function laminated layer 42 is the second gate metal layer 1421.

With reference to FIG. 14 and FIG. 15, in an embodiment, the second gate structure further includes a trench layer 1, and the trench layer 1 is located between the gate oxide layer 2 and the substrate 10.

Specifically, the trench layer 1 may include, but is not limited to a germanium layer or a silicon germanium layer.

With reference to FIG. 13, in an embodiment, the semiconductor structure further includes a buried gate word line 9, where the buried gate word line 9 is located in the device region.

It should be understood that although the steps in the flowcharts of FIGS. 1, 5, 6, 9 and 16 are shown in sequence according to the arrows, these steps are not necessarily executed in the sequence indicated by the arrows. The execution order of the steps is not strictly limited, and the steps may be executed in other orders, unless clearly described otherwise. Moreover, at least some of the steps in FIGS. 1, 5, 6, 9 and 16 may include a plurality of steps or stages. The steps or stages are not necessarily executed at the same time, but may be executed at different times. The execution order of the steps or stages is not necessarily carried out sequentially, but may be executed alternately with other steps or at least some of the steps or stages of other steps.

The technical features of the above examples can be employed in arbitrary combinations. To provide a concise description of these examples, all possible combinations of all technical features of the embodiment may not be described; however, these combinations of technical features should be construed as disclosed in the description as long as no contradiction occurs.

Only several embodiments of the present application are described in detail above, but they should not therefore be construed as limiting the scope of the present application. It should be noted that those of ordinary skill in the art can further make variations and improvements without departing from the conception of the present application. These variations and improvements all fall within the protection scope of the present application. Therefore, the protection scope of the present application should be subject to the protection scope defined by the appended claims.

1. A manufacturing method of a semiconductor structure, comprising:
providing a substrate, wherein the substrate comprises a device region and a peripheral region located at a periphery of the device region;
forming a gate oxide material layer in the peripheral region of the substrate, and forming a high-k dielectric material layer on an upper surface of the gate oxide material layer; and
forming a bit line structure in the device region, and forming a transistor structure in the peripheral region, wherein the transistor structure comprises a gate structure; the bit line structure comprises a bit line conductive layer and a bit line protective layer located on an upper surface of the bit line conductive layer; and the gate structure comprises:
a gate oxide layer;
a high-k dielectric layer, located on an upper surface of the gate oxide layer;
a gate conductive layer, located on the high-k dielectric layer; and
a gate protective layer, located on an upper surface of the gate conductive layer; wherein
the gate conductive layer and the bit line conductive layer are obtained by patterning a same conductive material layer, the bit line protective layer and the gate protective layer are obtained by patterning a same protective material layer, the gate oxide layer is obtained by patterning the gate oxide material layer, and the high-k dielectric layer is obtained by patterning the high-k dielectric material layer.

2. The manufacturing method of a semiconductor structure according to claim 1, wherein the gate structure further comprises a polysilicon layer, the polysilicon layer is located on the high-k dielectric layer, and the gate conductive layer is located on an upper surface of the polysilicon layer; and the forming a bit line structure in the device region, and forming a transistor structure in the peripheral region comprises:
forming a polysilicon material layer on the high-k dielectric material layer and a polysilicon material layer in the device region;
removing the polysilicon material layer in the device region;
forming a gate conductive material layer on an upper surface of the polysilicon material layer and a gate conductive material layer in the device region;
forming a protective material layer on an upper surface of the gate conductive material layer; and
patterning the protective material layer, the gate conductive material layer, the polysilicon material layer, the high-k dielectric material layer, and the gate oxide material layer to form the bit line structure and the gate structure.

3. The manufacturing method of the semiconductor structure according to claim 2, after the forming a gate oxide material layer in the peripheral region of the substrate, and forming a high-k dielectric material layer on an upper surface of the gate oxide material layer, the manufacturing method further comprises:
forming a metal-work-function material layer on an upper surface of the high-k dielectric material layer; and
patterning the metal-work-function material layer and the high-k dielectric material layer when the protective material layer, the gate conductive material layer, the polysilicon material layer, and the gate oxide material layer are patterned, to form a metal work function layer in the gate structure.

4. The manufacturing method of a semiconductor structure according to claim 3, wherein the peripheral region comprises a first region, a second region, a third region, and a fourth region, the transistor structure comprises a first transistor structure located in the first region, a second transistor structure located in the second region, a third transistor structure located in the third region, and a fourth transistor structure located in the fourth region; the first transistor structure comprises a first gate structure, the second transistor structure comprises a second gate structure, the third transistor structure comprises a third gate structure, and the fourth transistor structure comprises a fourth gate structure; the metal work function layer in the second gate structure and the metal work function layer in the fourth gate structure each comprise a first metal-work-function laminated layer and a second metal-work-function laminated layer, and the metal work function layer in the first gate structure and the metal work function layer in the third gate structure each comprise a second metal-work-function laminated layer; and the high-k dielectric material layer is further formed in the device region;
the forming a metal-work-function material layer on an upper surface of the high-k dielectric material layer comprises:
forming a first metal-work-function laminated material layer on the upper surface of the high-k dielectric material layer;
removing a part of the first metal-work-function laminated material layer located outside the second region and the fourth region; and
forming a second metal-work-function laminated material layer on an upper surface of the first metal-work-function laminated layer and a second metal-work-function laminated material layer on an upper surface of the exposed high-k dielectric material layer; and
after the removing the polysilicon material layer in the device region, and before the forming a gate conductive material layer on an upper surface of the polysilicon material layer and a gate conductive material layer in the device region, the manufacturing method further comprises:
removing the second metal-work-function laminated material layer located in the device region and the high-k dielectric material layer located in the device region.

5. The manufacturing method of a semiconductor structure according to claim 1, wherein in the processes of forming the bit line structure in the device region and forming the gate structure in the peripheral region, a bit line contact structure is also formed in the device region, and the bit line contact structure is located between the bit line structure and the substrate and is in contact with the bit line structure; the gate structure further comprises a polysilicon layer, the polysilicon layer is located on the high-k dielectric layer, the gate conductive layer is located on an upper surface of the polysilicon layer, and the polysilicon layer and the bit line contact structure are obtained by patterning a same polysilicon material layer; and the forming a bit line structure in the device region, and forming a transistor structure in the peripheral region, wherein the transistor structure comprises a gate structure comprises:
forming a polysilicon material layer on the high-k dielectric material layer and a polysilicon material layer in the device region;
forming a gate conductive material layer on an upper surface of the polysilicon material layer;
forming a protective material layer on an upper surface of the gate conductive material layer; and
patterning the protective material layer, the gate conductive material layer, the polysilicon material layer, the high-k dielectric material layer, and the gate oxide material layer to form the bit line contact structure, the bit line structure, and the gate structure.

6. The manufacturing method of the semiconductor structure according to claim 5, after the forming a gate oxide material layer in the peripheral region, and before the forming a polysilicon material layer on the high-k dielectric material layer and a polysilicon material layer in the device region, the manufacturing method further comprises:
forming a metal-work-function material layer on an upper surface of the high-k dielectric material layer; and
patterning the metal-work-function material layer when the protective material layer, the gate conductive material layer, the polysilicon material layer, the high-k dielectric material layer, and the gate oxide material layer are patterned, to form a metal work function layer in the gate structure.

7. The manufacturing method of a semiconductor structure according to claim 6, wherein the peripheral region comprises a first region, a second region, a third region, and a fourth region, the transistor structure comprises a first transistor structure located in the first region, a second transistor structure located in the second region, a third transistor structure located in the third region, and a fourth transistor structure located in the fourth region; the first transistor structure comprises a first gate structure, the second transistor structure comprises a second gate structure, the third transistor structure comprises a third gate structure, and the fourth transistor structure comprises a fourth gate structure; the metal work function layer in the second gate structure and the metal work function layer in the fourth gate structure each comprise a first metal-work-function laminated layer and a second metal-work-function laminated layer, and the metal work function layer in the first gate structure and the metal work function layer in the third gate structure each comprise a second metal-work-function laminated layer; the high-k dielectric material layer is further formed in the device region; and the forming a metal-work-function material layer on an upper surface of the high-k dielectric material layer comprises:
forming a first metal-work-function laminated material layer on the upper surface of the high-k dielectric material layer;
removing a part of the first metal-work-function laminated material layer located outside the second region and the fourth region; and
forming a second metal-work-function laminated material layer on an upper surface of the first metal-work-function laminated layer and a second metal-work-function laminated material layer on an upper surface of the exposed high-k dielectric material layer.
removing the second metal-work-function laminated material layer located in the device region and removing the high-k dielectric material layer located in the device region.

8. The manufacturing method of a semiconductor structure according to claim 4, wherein the first transistor structure is a thin oxygen N-type transistor, the second transistor structure is a thin oxygen P-type transistor, the third transistor structure is a thick oxygen N-type transistor, the fourth transistor structure is a thick oxygen P-type transistor, and before the forming a gate oxide material layer in the peripheral region, the manufacturing method further comprises:
forming a trench material layer in the second region; and patterning the trench material layer when the protective material layer, the gate conductive material layer, the polysilicon material layer, the gate oxide material layer, and the metal-work-function material layer are patterned, to form a trench layer in the second gate structure of the second transistor structure.

9. The manufacturing method of a semiconductor structure according to claim 1, before the forming a bit line structure in the device region, and forming a transistor structure in the peripheral region, the manufacturing method further comprises:
forming a buried gate word line in the device region.

10. A semiconductor structure, comprising:
a substrate, wherein the substrate comprises a device region and a peripheral region located at a periphery of the device region;
a bit line structure, located in the device region, wherein the bit line structure comprises a bit line conductive layer and a bit line protective layer located on an upper surface of the bit line conductive layer; and
a transistor structure, located in the peripheral region, wherein the transistor structure comprises a gate structure, and the gate structure comprises:
a gate oxide layer;
a high-k dielectric layer, located on an upper surface of the gate oxide layer;
a gate conductive layer, located on the high-k dielectric layer; and
a gate protective layer, located on an upper surface of the gate conductive layer; wherein
the gate conductive layer and the bit line conductive layer are obtained by patterning a same conductive material layer, the bit line protective layer and the gate protective layer are obtained by patterning a same protective material layer.

11. The semiconductor structure according to claim 10, wherein the semiconductor structure further comprises:
a bit line contact structure, wherein the bit line contact structure is located in the device region and located between the bit line structure and the substrate; and
the gate structure further comprises a polysilicon layer, the polysilicon layer is located on the high-k dielectric layer, and the gate conductive layer is located on an upper surface of the polysilicon layer.

12. The semiconductor structure according to claim 11, wherein the polysilicon layer and the bit line contact structure are obtained by patterning a same polysilicon material layer.

13. The semiconductor structure according to claim 11, wherein the gate structure further comprises:
a metal-work-function material layer, located on an upper surface of the high-k dielectric layer, wherein the polysilicon layer is located on an upper surface of the metal-work-function material layer.

14. The semiconductor structure according to claim 13, wherein the peripheral region comprises a first region, a second region, a third region, and a fourth region, the transistor structure comprises a first transistor structure located in the first region, a second transistor structure located in the second region, a third transistor structure located in the third region, and a fourth transistor structure located in the fourth region; the first transistor structure comprises a first gate structure, the second transistor structure comprises a second gate structure, the third transistor structure comprises a third gate structure, and the fourth transistor structure comprises a fourth gate structure; the metal-work-function material layer in the second gate structure and the metal-work-function material layer in the fourth gate structure each comprise a first metal-work-function laminated layer and a second metal-work-function laminated layer, and the metal-work-function material layer in the first gate structure and the metal-work-function material layer in the third gate structure each comprise a second metal-work-function laminated layer.

15. The semiconductor structure according to claim 14, wherein the first metal-work-function laminated layer comprises first gate metal layers and first work function layers laminated alternately and sequentially from bottom to top, and a top layer of the first metal-work-function laminated layer is the first gate metal layer; and the second metal-work-function laminated layer comprises second work function layers and second gate metal layers laminated alternately and sequentially from bottom to top, and a top layer of the second metal-work-function laminated layer is the second gate metal layer.

16. The semiconductor structure according to claim 14, wherein the second gate structure further comprises a trench layer, and the trench layer is located between the gate oxide layer and the substrate.

17. The semiconductor structure according to claim 10, wherein the semiconductor structure further comprises a buried gate word line, wherein the buried gate word line is located in the device region.

18. The manufacturing method of a semiconductor structure according to claim 7, wherein the first transistor structure is a thin oxygen N-type transistor, the second transistor structure is a thin oxygen P-type transistor, the third transistor structure is a thick oxygen N-type transistor, the fourth transistor structure is a thick oxygen P-type transistor, and before the forming a gate oxide material layer in the peripheral region, the manufacturing method further comprises:
forming a trench material layer in the second region; and patterning the trench material layer when the protective material layer, the gate conductive material layer, the polysilicon material layer, the gate oxide material layer, and the metal-work-function material layer are patterned, to form a trench layer in the second gate structure of the second transistor structure.
